(19) United States
(12) Patent Application Publication
(10) Pub. No.: US 2017/0103813 A1
(43) Pub. Date: Apr. 13, 2017

(54) EFFECTIVE PROGRAMMING METHOD FOR NON-VOLATILE FLASH MEMORY USING JUNCTION BAND TO BAND HOT ELECTRON

(71) Applicant: INTEGRATED SILICON SOLUTION, INC., Milpitas, CA (US)

(72) Inventors: Arthur Wang, HSIN CHU (TW); Sam Chou, HSIN CHU (TW); Jyh-Kuang Lin, HSIN CHU (TW)

(21) Appl. No.: 14/951,839

(22) Filed: Nov. 25, 2015

(30) Foreign Application Priority Data
Oct. 12, 2015 (TW) 104133415

(51) Int. Cl. G11C 16/14; H01L 27/115; H01L 29/10; G11C 16/04

(52) U.S. Cl. CPC G11C 16/14; G11C 16/0408; H01L 27/11524; H01L 29/1079

(57) ABSTRACT

Disclosed is an effective programming method for non-volatile flash memory including memory cells, each formed of a select transistor and a floating transistor. The method includes imposing a positive voltage onto a control gate of the floating transistor as a word line, supplying a zero voltage to a triple well, a deep N well, and a select gate of the select transistor to turn off the select transistor, and finally providing a moderate positive voltage to a drain of the control transistor. Owing to the junction band-to-band tunneling effect, the electron of the hole-electron pair generated between the junction of the bit line and the triple well leaps to the floating gate of the floating transistor driven by the positive electric field to form a higher threshold voltage for the memory cell such that the process of programming is accomplished.

### CROSS-REFERENCE TO RELATED APPLICATION

This application claims the priority of Taiwan patent application No. 104133415, filed on Oct. 12, 2015. All disclosure of which is incorporated herein by reference in its entirety.

### BACKGROUND OF THE INVENTION

1. Field of the Invention

The present invention generally relates to an effective programming method for non-volatile flash memory, and more specifically to an effective programming method using junction band to band hot electrons to replace channel hot electrons so as to solve the problem of low efficiency of injection for high programming current, greatly improve complexity of circuit design, and increase the amount of memory cells for being programmed at one time.

2. The Prior Arts

As the increasing progress of technology in the semiconductor industry, various integrated circuits (ICs) have been implemented such that advanced and fancy functions are provided by electronic products such as personal computers, mobile phones. Besides high performance processors, these electronic products need specific memory to store temporary data for processing during operation, like RAM (random access memory). However, the data stored in RAM will completely disappear after power off To store preset system parameters or the firmware such as BIOS (basic input/output system) for running the operating system (OS), the non-volatile flash memory has been developed to store and sustain the data without loss after power off, especially the flash memory provided with both writing and erasing functions for a great deal of data.

In general, two primary types of the non-volatile flash memory are NOR gate flash memory and NAND flash memory. Traditionally, NOR memory cells built in the NOR flash memory employ CHE (channel hot electron) to perform programming or writing, and the written data is erased by a process of FN (Fowler-Nordheim).

Specifically, the traditional programming process employs the select transistor to keep the source of the stacked-gate transistor sees only one bit line. The source of the select transistor in the CHE memory cell is connected to the bit line and applied by 0V, its drain is connected to the source line and applied by 5V, and the control gate is connected to the word line and applied by a positive voltage up to 12V. As a result, the channel hot electrons (CHEs) are drawn to migrate to the floating gate, taken as the state 0 such that the data read out from the memory cell is data “0”.

However, one shortcoming in the prior arts is that the programming process needs a high programming current up to about 10⁻⁴ A with low injection efficiency, which causes more complex circuit design and limits the volume of memory cells to be programmed at one time. Therefore, it is greatly needed to provide a new programming method for effectively programming non-volatile flash memory, which replaces the traditional channel hot electrons with the band-to-band hot electrons to avoid the problem of using high programming current with low injection efficiency during the programming flow, improve complexity of circuit design and increase the amount of memory cells to be programmed at one time, thereby overcoming the above problems in the prior arts.

### SUMMARY OF THE INVENTION

The primary objective of the present invention is to provide an effective programming method for non-volatile flash memory. The non-volatile flash memory comprises a plurality of select transistors and a plurality of floating transistors, and each select transistor and the corresponding floating transistor forms a memory cell. Each of the select transistor and the select transistor is preferably implemented by an N transistor. Specifically, the memory cell is provided in a triple P well, and the triple P well is configured in a deep N well. Additionally, the deep N well is provided in a P substrate.

The floating transistor has a floating gate and a control gate, which are not electrically connected together. A source of the select transistor is connected to a common source line, a drain of the select transistor is connected to a source of the floating transistor, and a drain of the floating transistor is connected to a bit line. The control gate of the floating transistor connected to a word line.

More specifically, the effective programming method of the present invention generally comprises the first, second, third and fourth programming steps, which are sequentially performed. In the first programming step, a positive voltage is applied to the control gate of the floating transistor. The second programming step applies a zero voltage or a negative voltage to the triple P well and the deep N well. Then, the zero voltage or the negative voltage is applied to a select gate of the select transistor for turning off the select transistor in the third programming step. Finally, the fourth programming step is performed to apply a moderate positive voltage to the drain of the floating transistor. Since an effect of junction band to band tunneling (BTBT) exerted on the junction between the bit line and the triple P well, electrons of hole-electron pairs are caused to migrate to the floating gate so as to increase the threshold voltage of the memory cell, taken as a state 0.

In addition, an erasing process is used to change the state 0 of the above floating gate. In general, the erasing process comprises the first, second, third and fourth erasing steps, which are sequentially performed.

In the first erasing step, another negative voltage is applied to the control gate, and in the second erasing step, the zero voltage is applied to the select gate, and the floating source line is applied by the zero voltage or is floating. Then, another positive voltage is applied to the triple P well and the deep N well in the third erasing step. The fourth erasing step is finally performed to keep the drain of the floating transistor floating such that the electrons in the floating gate are forces to migrate to the triple P well due to an effect of Fowler-Nordheim tunneling so as to reduce the threshold voltage of the memory cell, taken as a state 1.

Therefore, the method of the present invention exhibits some advantages such as a simple processing flow without additional steps used in traditional programming process for flash memory. In particular, the memory cell used in the present invention to be programmed is of a double transistors structure, which can prevent the problem of over-erase while the floating gate is programmed. Furthermore, the threshold voltage of the floating transistor after the erasing process can be a negative value, and the issue of charge accumulation thus seldom happens so as to perform excellent reliability. Besides higher efficiency for the BTBT (Band-to-Band tunneling transistor) compared with the traditional CHE (Channel Hot Electron Transistor), the present invent can program a larger amount of memory cells at one time using a smaller programming current, like pages of memory cells in one sector. Also, the transistors are turned off during the programming and erasing processes, and it is thus easy to scale down the size without the concern of device punch-through.

As for the applications for multiple levels, the method of the present invention can meets the requirement just by applying different, appropriate bias to the control gate during the programming process, and the feature of self-convergent mechanism further reduces the complexity of circuit design for verification and the chip size.

### BRIEF DESCRIPTION OF THE DRAWINGS

The present invention will be apparent to those skilled in the art by reading the following detailed description of a preferred embodiment thereof, with reference to the attached drawings, in which:

FIG. 1 is a flowchart showing the respective steps of the effective programming method for non-volatile flash memory according to the first embodiment of the present invention;

FIG. 2 is a view showing the non-volatile flash memory used in the present invention;

FIGS. 3 and 4 are simple and cross sectional views showing the memory cell according to the present invention, respectively;

FIG. 5 is a flowchart showing the respective steps of the erasing process according to the present invention; and

FIG. 6 is a view showing the memory cell under the erasing process according to the present invention.

### DETAILED DESCRIPTION OF THE PREFERRED EMBODIMENT

The accompanying drawings are included to provide a further understanding of the invention, and are incorporated in and constitute a part of this specification. The drawings illustrate embodiments of the invention and, together with the description, serve to explain the principles of the invention.

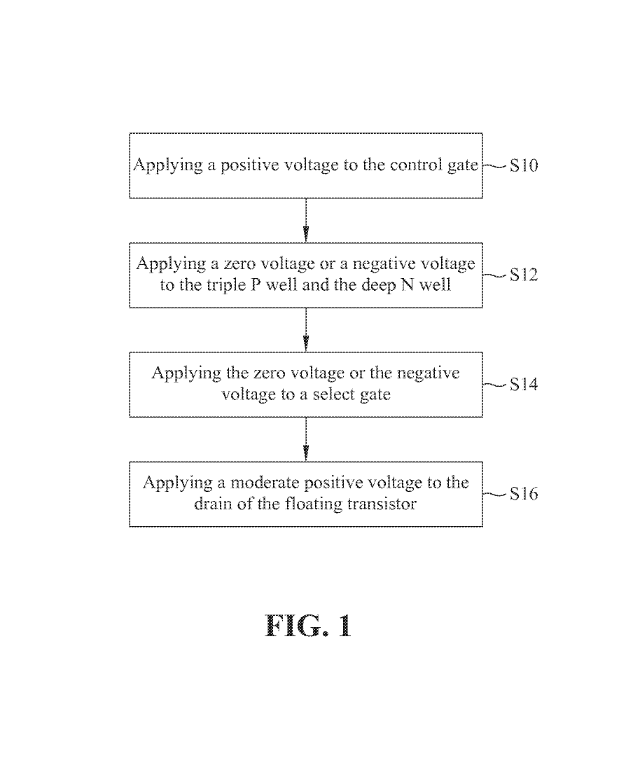

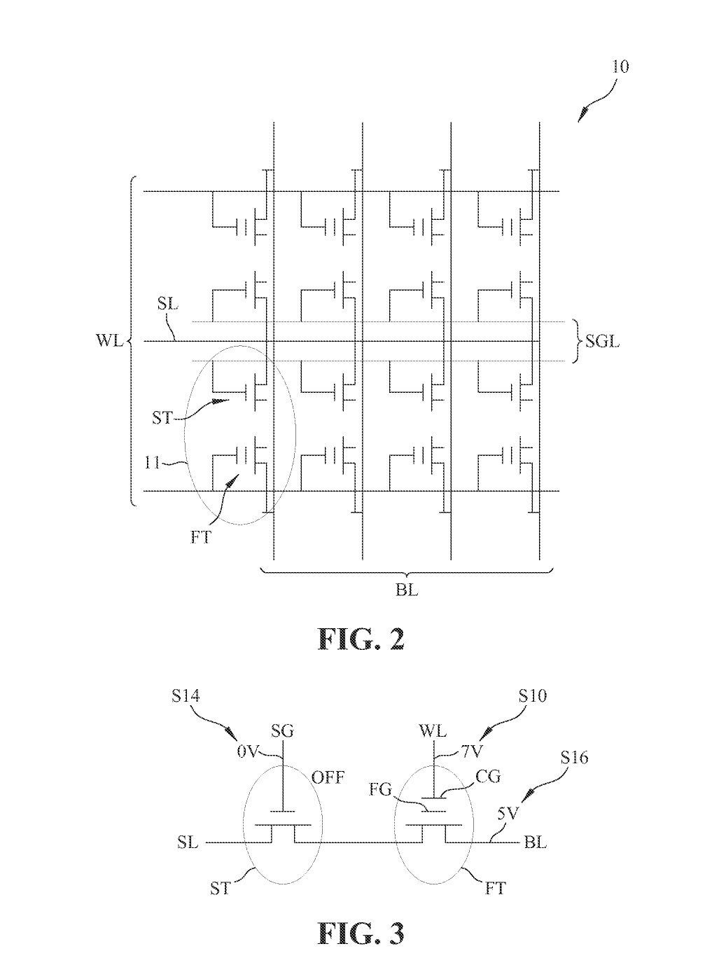

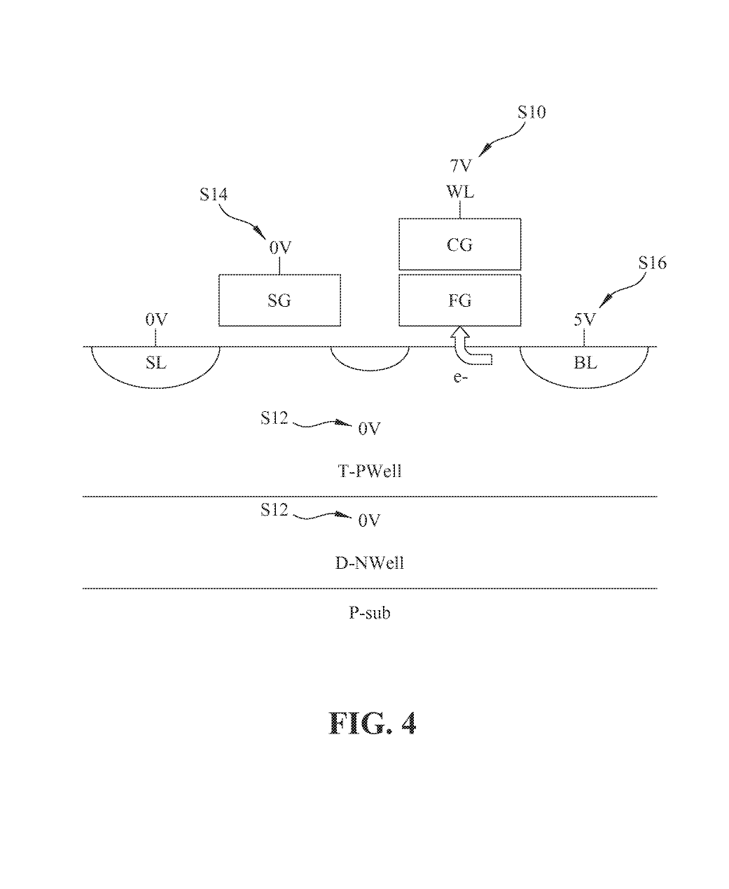

Please refer to FIG. 1 illustrating the respective steps of the effective programming method for non-volatile flash memory according to the first embodiment of the present invention. As shown in FIG. 1, the effective programming method of the present invention generally comprises the first, second, third and fourth programming steps S10, S12, S14 and S16, which are sequentially performed. To clearly explain the key features of the present invention, please refer to FIGS. 2, 3 and 4, wherein FIG. 2 is a view showing the non-volatile flash memory 10, FIG. 3 is a view of a single memory cell 11, and FIG. 4 is a cross sectional view of the single memory cell 11.

As shown in FIGS. 2, 3 and 4, the non-volatile flash memory 10 substantially comprises a plurality of select transistors ST and a plurality of floating transistors FT, each select transistor ST and the corresponding floating transistor FT forming one memory cell. Each of the select transistor ST and the select transistor FT is preferably implemented by an N transistor. Furthermore, the memory cell is provided in a triple P well T-PWell, and the triple P well T-PWell is configured in a deep N well D-NWell. Additionally, the deep N well D-NWell is provided in a P substrate P-sub.

As for the select transistor ST, its source, drain and select gate SG are connected to the common source line SL, the source of the floating transistor FT, and the select gate line SGL, respectively.

The floating transistor FT has a floating gate FG and a control gate CG, which are not electrically connected together. Specifically, the drain of the floating transistor ST is connected to the bit line BL, and the control gate CG of the floating transistor FT connected to the word line WL.

The effective programming method according to the present invention begins at the first programming step S10, in which a positive voltage is applied to the control gate CG of the floating transistor FT, that is, the word line WL. The second programming step S12 is then performed to apply a zero voltage or a negative voltage to the triple P well T-PWell and the deep N well D-NWell. In the third programming step S14, the zero voltage or the negative voltage is applied to the select gate SG of the select transistor ST (that is, the select gate line SGL) for turning off the select transistor ST, and finally, the fourth programming step S16 is performed to apply a moderate positive voltage to the drain of the floating transistor FT (that is, the bit line SGL) so as to accomplish the programming process. It is preferred that the positive voltage is about 7+/−3V, and the moderate positive voltage is about 5V+/−1.5V.

More specifically, based on the above mentioned process, the electrons e− of hole-electron pairs in the junction between the bit line BL and the triple P well are drawn by the electric field to easily migrate to the floating gate FG of the floating transistor FT due to the effect of junction band to band tunneling (BTBT), as shown by the arrow in FIG. 4. Thus, the threshold voltage Vt of the memory cell is increased, and taken as a state 0. In other words, the data “0” can be read out from the memory cell 11.

It should be noted that the method of the present invention is totally different from the traditional programming process, which employs the CHE (Channel Hot Electron Transistor) to program the CHE memory cells. In the prior arts, the select transistor is used to make sure the bit line of the stack gate (SG) sees only one bit, the source of the select transistor in the CHE memory is connected to the bit line and applied by 0V, and the drain of the select transistor is connected to the source line and applied by 5V. In particular, the control gate of the select transistor is connected to the word line and applied by a positive voltage up to 12V. At this time, the CHE in the N channel migrate to the floating gate of the floating transistor, specified by the state 0. However, the control gate of the present invention only needs a lower positive voltage like 7V, and the select transistor is turned off such that no N channel is formed, and the carriers injecting into the floating gate are no more the CHE, but the electrons e− under the effect of BTBT.

In other words, the electrical connection and the programming voltage for the memory cells implemented by the present invention are substantially different from those of the traditional flash memory. In addition, the method of the present invention employs the lower voltage of 7V instead of the higher voltage of 12V so as to greatly improve reliability in actual operation without any adverse effect on the electronic devices, which often happens at the high voltage applications.

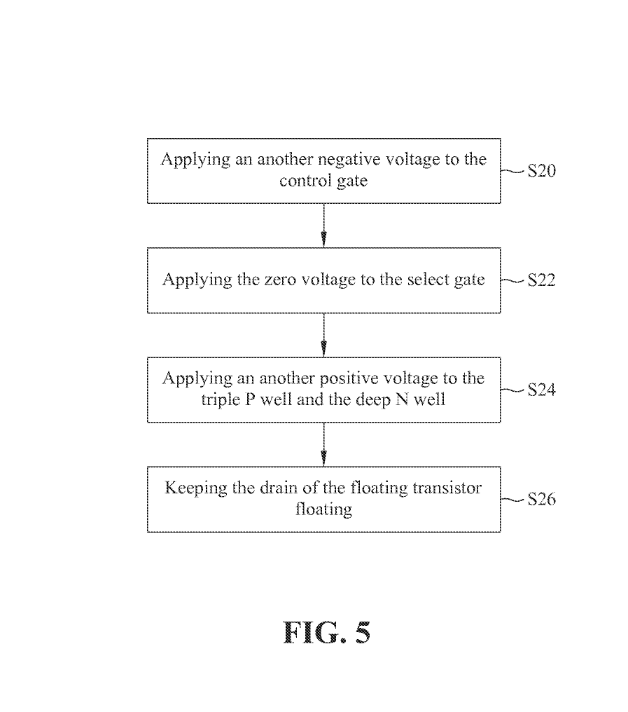

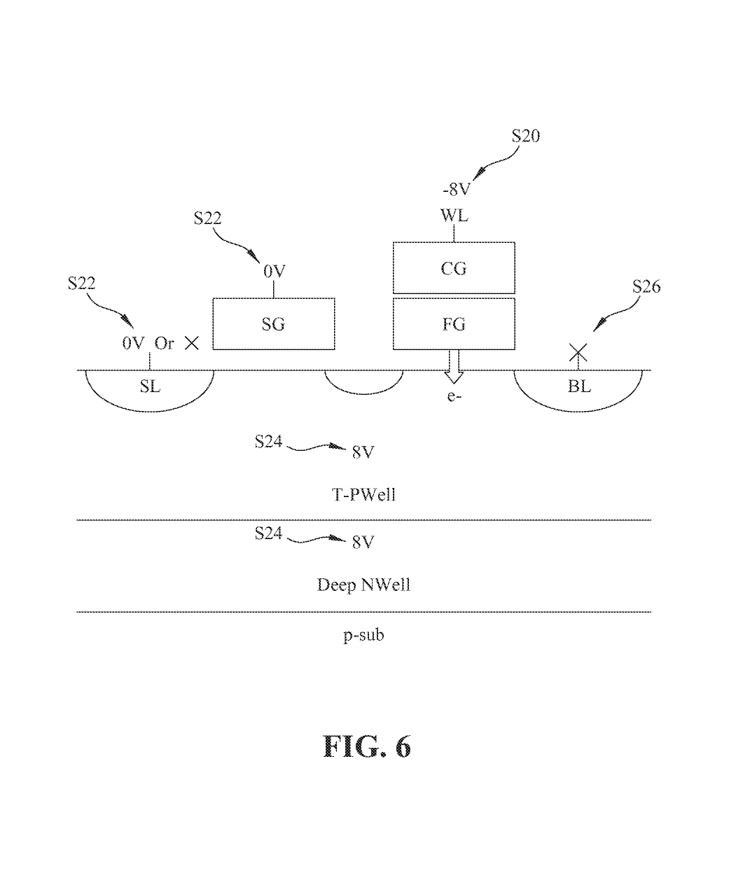

Furthermore, the present invention can change the state 0 to the state 1 of the respective memory cells through the erasing process. The aspects of the erasing process will be described in detail with reference to FIGS. 5 and 6, which show the flowchart for the respective steps of the erasing process, and the cross section of the memory cell under the erasing process, respectively.

As shown in FIG. 5, the erasing process comprises the first, second, third and fourth erasing steps S20, S22, S24 and S26, which are sequentially performed. Specifically, as shown in FIG. 6, the first erasing step S20 is first performed to apply another negative voltage like −8V to the control gate CG, and then in the second erasing step S22, the zero voltage is applied to the select gate SG, and the floating source line is applied by the zero voltage or is floating. As for the third erasing step S24, another positive voltage like about 8V is applied to the triple P well T-PWell and the deep N well D-NWell. Finally, the fourth erasing step S26 is performed to keep the drain of the floating transistor FT floating (that is, the bit line BL is floating) such that the electrons trapped in the floating gate FG are forces to migrate to the triple P well T-PWell due to the effect of Fowler-Nordheim tunneling and the threshold voltage of the memory cell is reduced as the state 1.

Preferably, the another negative voltage is about −8V+/−3V, and the another positive voltage is about 8V+/−3V.

In addition to the programming function for the non-volatile flash, the present invention provides the erasing feature to change the state of the respective memory cells so as to implement the repetitive operation of programming/erasing the non-volatile flash for many times.

From the above mentioned, one aspect of the present invention is that the non-volatile flash memory is effectively programmed by the method, and the advantage of the simpler processing flow is acquired without additional steps used in traditional programming process so as to improve reliability and prevent the problem of over-erase. Additionally, the threshold voltage of the floating transistor after being erased can be low as a negative value, and the issue of charge accumulation is less concerned. As a result, electrical reliability is further increased.

Another aspect of the present invention is that carrier injection is more efficient, which is appropriate for simultaneously programming a large amount of memory cells at a lower programming current. Particularly, the transistors are turned off during the programming and erasing processes such that the chip size is easily shrink without the risk of element punching-through. Also, the method of the present invention is applicable to the multiple level applications by just applying different, appropriate bias to the control gate during the programming process. The feature of self-convergent mechanism provided by the present invention further reduces the complexity of circuit design for verification and the die size.

Although the present invention has been described with reference to the preferred embodiments thereof, it is apparent to those skilled in the art that a variety of modifications and changes may be made without departing from the scope of the present invention which is intended to be defined by the appended claims.

1. An effective programming method for non-volatile flash memory having a plurality of select transistors and a plurality of floating transistors, each select transistor and a corresponding floating transistor forming a memory cell, each of the select transistor and the floating transistor being implemented by an N transistor, each memory cell provided in a triple P well, the triple P well provided in a deep N well, the deep N well provided in a P substrate, the floating transistor having a floating gate and a control gate not electrically connected together, a source of the select transistor connected to a common source line, a drain of the select transistor connected to a source of the floating transistor, a drain of the floating transistor connected to a bit line, the control gate of the floating transistor connected to a word line, the effective programming method comprising:
a first programming step applying a positive voltage to the control gate of the floating transistor;
a second programming step applying a zero voltage or a negative voltage to the triple P well and the deep N well;
a third programming step applying the zero voltage to a select gate of the select transistor for turning off the select transistor; and
a fourth programming step applying a moderate positive voltage to the drain of the floating transistor,
wherein electrons of hole-electron pairs are caused to migrate to the floating gate by an effect of junction band to band tunneling (BTBT) in a junction between the bit line and the triple P well so as to increase a threshold voltage of the memory cell as a state 0.

2. The effective programming method for non-volatile flash memory as claimed in claim 1, wherein the positive voltage is 7+/−3V, and the moderate positive voltage is 5V+/−1.5V.

3. The effective programming method for non-volatile flash memory as claimed in claim 1, wherein the state 0 of the floating gate is changed by an erasing process, comprising:
a first erasing step applying another negative voltage to the control gate;
a second erasing step applying the zero voltage to the select gate, and applying the zero voltage to a floating source line or floating the floating source line;
a third erasing step applying another positive voltage to the triple P well and the deep N well; and
a fourth erasing step keeping the drain of the floating transistor floating such that the electrons in the floating gate are forced to migrate to the triple P well due to an effect of Fowler-Nordheim tunneling so as to reduce the threshold voltage of the memory cell as a state 1.

4. The effective programming method for non-volatile flash memory as claimed in claim 3, wherein the another negative voltage is −8V+/−3V, and the another positive voltage is 8V+/−3V.
